(19) United States
(12) Patent Application Publication
(10) Pub. No.: US 2011/0147698 A1
(43) Pub. Date: Jun. 23, 2011

(54) FIELD EMISSION DEVICE AND METHOD OF FORMING THE SAME

(75) Inventors: Jung Won YOO, Gyeonggi-do (KR); Jae Young PARK, Gyeonggi-do (KR); Young Don PARK, Gyeonggi-do (KR); Soo Young PARK, Seoul (KR); Young Suk KIM, Gyeonggi-do (KR)

(73) Assignee: NANOPACIFIC INC., Gyeonggi-do (KR)

(21) Appl. No.: 12/786,411

(22) Filed: May 24, 2010

(30) Foreign Application Priority Data
Dec. 17, 2009 (KR) 10-2009-0126186

(51) Int. Cl. H01L 49/00

(52) U.S. Cl. 257/10; 977/742; 257/E49.001

(57) ABSTRACT

A field emission device is provided. The field emission device includes a first substrate including a gate electrode including gate lines respectively extending in first, second, and third direction and a cathode electrode including cathode lines respectively extending in the first, second, and third directions; a second substrate facing the first substrate and including an anode electrode; and a space between the first and second substrates.

### CROSS-REFERENCE TO RELATED APPLICATIONS

This U.S. non-provisional patent application claims priority under 35 U.S.C. §119 to Korean Patent Application No. 10-2009-0126186, filed on Dec. 17, 2009, the entirety of which is hereby incorporated by reference.

### BACKGROUND

The present disclosure herein relates to a field emission device and a method of forming the same.

A field emission device designates a device utilizing a component that electrons are emitted from a cathode electrode through applying an electric field. The field emission device allows efficient power consumption of a component to be achieved even with low manufacturing cost. Therefore, the field emission device has been widely used in display, lighting, and microwave elements and various applications including a sensor.

Various types of field emission devices may be implemented according to the structure of an electrode and characteristics of an emitter.

### SUMMARY

Embodiments of the inventive concept provide a field emission device with improved reliability.

According to embodiments of the inventive concept, the field emission device may include a gate electrode including a first gate line extending a first direction of a first substrate, a plurality of second gate lines branching from the first gate line and extending a second direction that is not in parallel with the first direction, and third gate lines branching from the second gate lines; a cathode electrode including a first cathode line being in parallel with the first gate line on the first substrate, a plurality of second cathode lines branching from the first cathode line and being in parallel with the second gate lines, and third cathode lines branching from the second cathode lines and being interlocked with the third gate lines; a second substrate disposed in parallel with the first substrate and spaced apart from the first substrate at a predetermined distance; an anode electrode opposite to the gate electrode and the cathode electrode and a phosphor layer on the anode electrode, on the second substrate; and a spacer making the first and second substrates spaced apart from each other. The gate electrode and the cathode electrode constitute a driving unit.

According to an example embodiment of the inventive concept, the spacer may be disposed at a region on the first substrate where the gate electrode and the cathode electrode are not disposed.

According to an example embodiment of the inventive concept, the cathode electrode may include second cathode lines having widths which are greater than those of the first and third cathode lines. Widths of the first, second, and third cathode lines may be defined as widths in perpendicular directions to directions of the first, second, and third direction, respectively. The cathode electrode may further include other second cathode lines having widths which are substantially equal to those of the first and third cathode lines.

According to an example embodiment of the inventive concept, an entire bottom surface of one spacer may be disposed on one second cathode line.

According to an example embodiment of the inventive concept, the gate electrode may include second gate lines having widths which are greater than those of the first and third gate lines. In this case, widths of the first, second, and third gate lines are defined as widths in perpendicular directions to directions of the first, second, and third direction, respectively.

According to an example embodiment of the inventive concept, the gate electrode may further include other second gate lines having widths which are substantially equal to those of the first and third gate lines.

According to an example embodiment of the inventive concept, an entire bottom surface of one spacer may be disposed on one second gate line.

According to an example embodiment of the inventive concept, the field emission device may further include an insulating layer covering the gate electrode and the cathode electrode. The insulating layer may include a mixture of a low temperature glass frit and an inert inorganic particle.

According to an example embodiment of the inventive concept, the field emission device may further include an emitter on the insulating layer. The emitter may include a carbon nanotube.

### BRIEF DESCRIPTION OF THE DRAWINGS

The inventive concept will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the inventive concept.

FIGS. 1A to 1C illustrate a field emission device according to an embodiment of the inventive concept, FIGS. 1B and 1C being cross-sectional views taken along the line I-II in FIG. 1A.

FIGS. 2A and 2B illustrate a field emission device according to another embodiment of the inventive concept, FIG. 2B being a cross-sectional view taken along the line III-IV in FIG. 2A.

FIGS. 3A and 3B illustrate a method of forming a field emission device according to an embodiment of the inventive concept.

### DETAILED DESCRIPTION OF THE EMBODIMENTS

The inventive concept will now be described more fully hereinafter with reference to the accompanying drawings, in which preferred embodiments of the inventive concept are shown. However, the inventive concept may be embodied in many different forms and should not be construed as limited to the embodiments set forth herein. Rather, these embodiments are provided so that this disclosure will be thorough and complete, and will fully convey the scope of the inventive concept to those skilled in the art. As used herein, the term “and/or” includes any and all combinations of one or more of the associated listed items. It will also be understood that when a layer is referred to as being “on” another layer or substrate, it can be directly on the other layer or substrate, or intervening layers may also be present. In the drawings, embodiments of the inventive concept are not limited to the specific examples provided herein and are exaggerated for clarity. Though terms like a first, a second, and a third are used to describe various regions and layers in various embodiments of the inventive concept, the regions and the layers are not limited to these terms. These terms are only used to distinguish one component from another component. Furthermore, the same reference numerals denote the same elements throughout the specification.

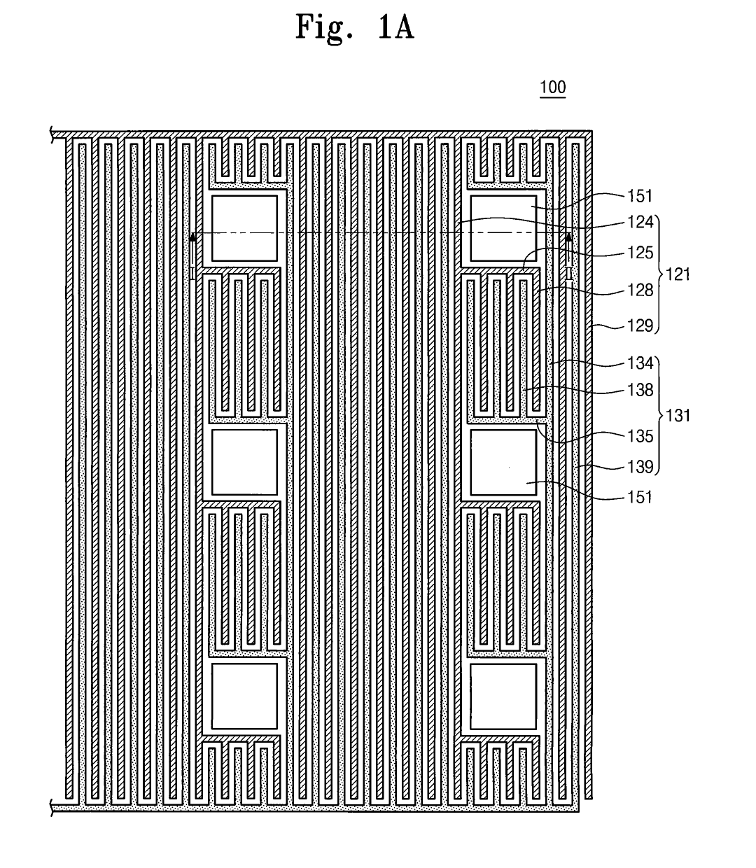

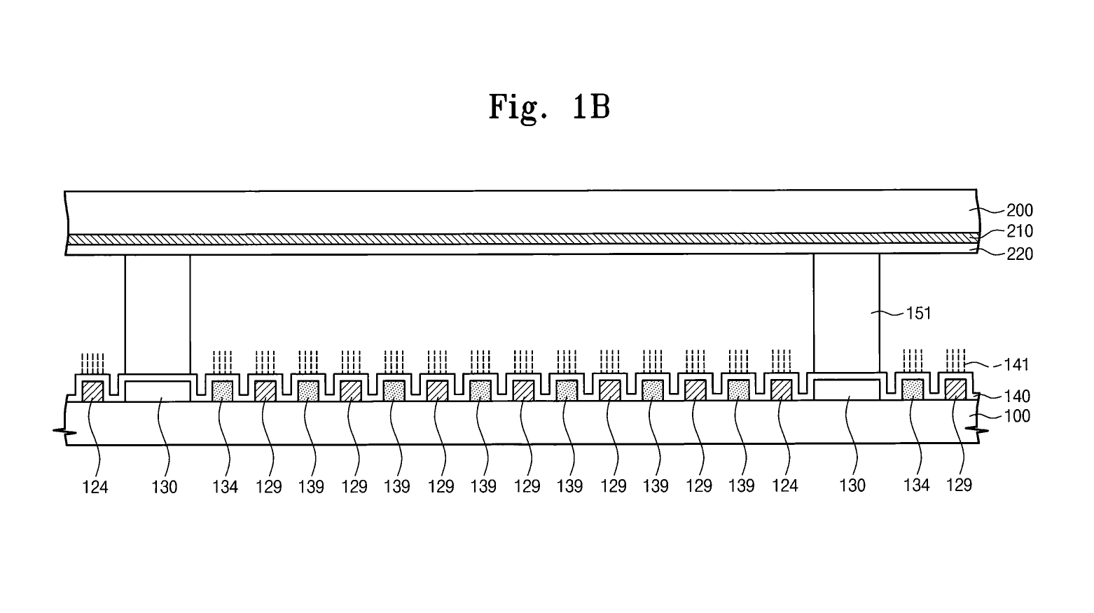

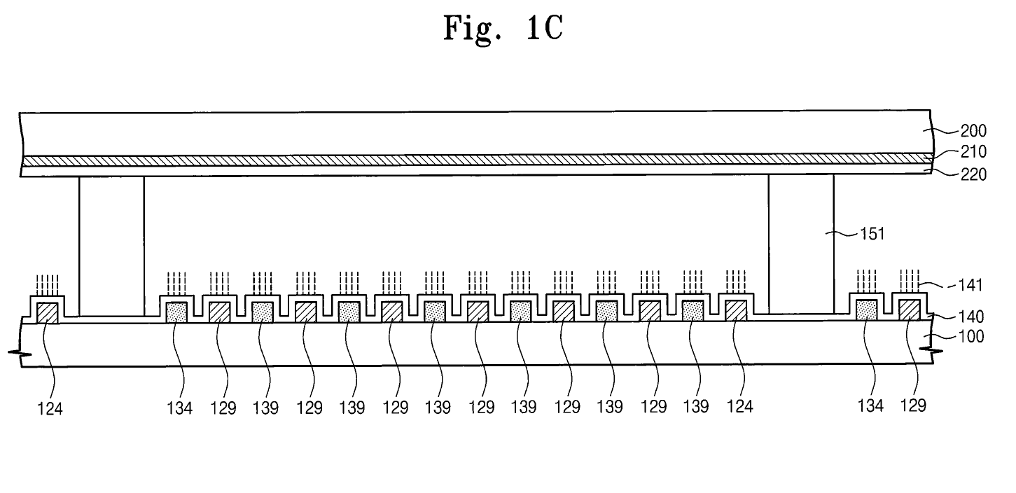

Referring to FIGS. 1A and 1B, a field emission device according to an embodiment of the inventive concept will now be described in detail. FIG. 1A is a plan view of a field emission device according to an embodiment of the inventive concept FIG. 1B is a cross-sectional view taken along the line I-II in FIG. 1A.

Referring to FIGS. 1A and 1B, a cathode substrate 100 and an anode substrate facing the cathode substrate 100 are disposed. The cathode substrate 100 and the anode substrate 200 may be in parallel with each other. The cathode substrate 100 and the anode substrate 200 may include at least one selected from the dielectric group consisting of glass, alumina, quartz, and silicon. A spacer 151 may be disposed between the cathode substrate 100 and the anode substrate 200. The spacer 151 may support a space between the cathode substrate 100 and the anode substrate 200 such that the cathode substrate 100 and the anode substrate 200 are spaced apart from each other. A vacuum state may be maintained between the cathode substrate 100 and the anode substrate 200. For example, a vacuum level between the cathode substrate 100 and the anode substrate 200 may be about 10⁻⁷ Torr.

A gate electrode 131 and a cathode electrode 121 are disposed on the cathode substrate 100. The gate electrode 131 and the cathode electrode 121 may be collaterally disposed on a plane of the cathode substrate 100. That is, the gate electrode 131 and the cathode electrode 121 may be disposed in a lateral type. The gate electrode 131 and the cathode electrode 121 may be disposed to have a predetermined horizontal distance on the cathode substrate 100.

The gate electrode 131 may include a first gate line 134 extending in a first direction on the plane of the cathode electrode 100, a plurality of second gate lines 135 branching from one side of the first gate line 134, and a plurality of third gate lines 138 branching from one side of the second gate line 135. The second gate lines 135 may extend in a second direction which is not in parallel with the first direction, and the third gate lines 138 may extend in a third direction which is not in parallel with the second direction. According to an example embodiment, the first direction and the third direction may be in parallel with each other and the second direction may be perpendicular to the first and third directions.

The first, second, and third gate lines 134, 135, and 138 may be connected to constitute a pattern. According to an example embodiment, widths of the first gate line 134, the second gate lines 135, and the third gate lines 138 may be substantially equal to one another.

The gate electrode 131 may further include fourth gate lines 139. The fourth gate lines 139 may extend in the first direction and be disposed at regular distance from the first gate line 134 in parallel with the first gate line 134. Unlike the first gate line 134, the fourth gate lines 139 disposed in parallel with the first direction do not include branch lines. That is, among the lines of the gate electrode 131 extending in the first direction, a line from which the second gate lines 135 branch is the first gate line 134 and a line from which the second gate lines 135 do not branch is the fourth gate line 139.

According to an example embodiment, the first gate line 134 and the fourth gate line 139 may be connected by one line. The one line may also be included in the gate electrode 131.

The gate electrode 131 may include at least one selected from metals including chrome (Cr), aluminum (Al), nickel (Ni), cobalt (Co), platinum (Pt), gold (Au), titanium (Ti), tungsten (W), and zinc (Zn). Alternatively, the gate electrode 131 may include at least one selected from conductive metal compounds including indium tin oxide (ITO).

The cathode electrode 121 may include a first cathode line 124, a plurality of second cathode lines 125 branching from one side of the first cathode line 124, and a third cathode line 128 branching from one side of the second cathode line 125. The second cathode line 125 may extend in a second direction which is not in parallel with the first direction, and the third cathode lines 128 may extend in a third direction which is not in parallel with the second direction. According to an example embodiment, the first and third directions may be parallel with each other, and the first and second directions may be substantially perpendicular to each other.

The cathode electrode 121 may further include fourth cathode lines 129. The fourth cathode lines 129 may extend in the first direction and be disposed at regular distance from the first cathode line 124 in parallel with the first cathode line 124. Unlike the first cathode line 124, the fourth cathode lines 129 disposed in parallel with the first direction do not include branch lines. That is, among the lines of the cathode electrode 121 extending in the first direction, a line from which the second cathode lines 125 branch is the first cathode line 124 and a line from which the second cathode lines 125 do not branch is the fourth cathode line 129.

According to an example embodiment, the first cathode line 124 and the fourth cathode line 129 may be connected by one line. The one line may also be included in the cathode electrode 121.

The first cathode line 124 may be in parallel with the first gate line 134. The second cathode lines 125 branching from the first cathode line 124 may be in parallel with the second gate lines 135. The second gate lines 135 and the second cathode lines 125 may be alternately arranged. Second gate lines 135 branching from one first gate 134 and second cathode lines 125 branching from one first cathode line 124 disposed in parallel with the first gate line 134 may be interlocked with each other. The third cathode lines 128 may be in parallel with the third gate lines 138. The third cathode lines 128 and the third gate lines 138 may be alternately arranged. Third gate lines 138 branching from one second gate line 135 and third cathode lines 128 branching from one second cathode line 135 adjacent to the one second gate line 135 may be interlocked with each other. The fourth cathode line 129 and the fourth gate line 139 may also be interlocked with each other and may be disposed in parallel with each other.

The cathode electrode 121 may include at least one selected from metals including chrome (Cr), aluminum (Al), nickel (Ni), cobalt (Co), platinum (Pt), gold (Au), titanium (Ti), tungsten (W), and zinc (Zn). Alternatively, the cathode electrode 121 may include at least one selected from conductive metal compounds including indium tin oxide (ITO).

A pattern 130 may be disposed between a second gate line 135 and a second cathode line 125 which are adjacent to each other. The pattern 130 may have a greater width than a spacer which will be described later. The pattern 130 may be electrically and/or spatially spaced apart from the gate electrode 131 and the cathode electrode 121. The pattern 130 may be omitted, as shown in FIG. 1C.

An insulating layer 140 may be disposed on the gate electrode 131 and the cathode electrode 121. The insulating layer 140 may conformally cover the gate electrode 131 and the cathode electrode 121. Alternatively, the insulating layer 140 may have a planar top surface while filling a space between the gate electrode 131 and the cathode electrode 121. The insulating layer 140 may have a thickness ranging from 0.01 to 20 micrometers. The insulating layer 140 may include a mixture of a low temperature glass frit and an inert inorganic particle. The inert inorganic particle may include at least one selected from the group consisting of alumina, silicon, silica, titanium dioxide, and a combination thereof.

Emitters 141 may be disposed on the insulating layer 140. The emitters 141 may extend along the gate electrode 131 and the cathode electrode 121. According to an example embodiment, the emitters 141 may be disposed on the third gate lines 138 and the third cathode lines 128 in form of a line. In addition, the emitters 141 may be disposed on first gate lines 131 overlapping the third gate lines 138 in a second direction and first cathode lines 121 overlapping the third cathode lines 128 in a second direction. The emitters 141 may include a carbon nanotube.

The spacer 151 may be disposed between adjacent second gate lines 135 and/or between adjacent second cathode lines 125. The spacer 151 may be disposed between a pair of second lines which comprises one second gate line 135 and one second cathode line adjacent to the one second gate line 135. The second cathode line 135 constituting the pair of second lines may include third cathode lines 128 interlocked with third gate lines 138 branching from the one second gate line 135. The spacer 151 may exhibit a pillar shape such as, for example, a cylindrical shape or a square pillar shape.

The spacer 151 may do not overlap the gate electrode 131 and the cathode electrode 121 in the first and second directions. In other words, the spacer 151 may be disposed on the insulating layer 140 and the gate electrode 131 and the cathode electrode 121 may not be disposed below the spacer 151. According to an example embodiment, the spacer pattern 130 may be disposed below the insulating layer 140 below the spacer 151. The spacer pattern 130 may be a pattern insulated from the gate electrode 131 and the cathode electrode 121. Alternatively, the pattern 130 may be omitted. In this case, the spacer 151 may have a bottom surface disposed to be lower than top surfaces of the gate electrode 131 and the cathode electrode 121. In addition, a top surface of the insulating layer 140 below the bottom surface of the spacer 151 may be disposed to be lower than a top surface of the adjacent insulating layer 140.

Because the spacer 151 according to embodiments of the inventive concept is not formed on a plurality of gate electrode lines and/or cathode electrode lines, device characteristic degradation caused by the spacer 151 may be suppressed. Specifically, in the case that one spacer is formed on a plurality of gate lines and/or a plurality of cathode lines, arcing and/or abnormal emitting effect resulting from charging and discharging may occur between a plurality of lines connected to the one spacer. Moreover, Characteristics of a field emission device may be deteriorated by a short circuit and/or electrical conducting of the adjacent electrode lines. The short circuit and the electrical conducting can be caused by glue used to adhere the spacer in a process for forming the spacer. However, according to embodiments of the inventive concept, because the spacer 151 is not formed on a plurality of electrode lines, electrical characteristic degradation caused by the spacer 151 and the step of forming the spacer 151 may be reduced. Thus, a field emission device with improved stability may be provided.

An anode electrode 210 and a phosphor layer 220 may be disposed on one surface of the anode substrate 200. The anode substrate 210 may be disposed such that the anode electrode 210 and the phosphor layer 220 face the cathode substrate 100.

The anode electrode 210 may exhibit one of line, plane, and lattice shapes. The anode electrode 210 may include at least one selected from the group consisting of transparent conductive materials containing indium tin oxide (ITO). The phosphor layer 220 may include white phosphor where red (R), green (G), and blue (B) phosphors are mixed.

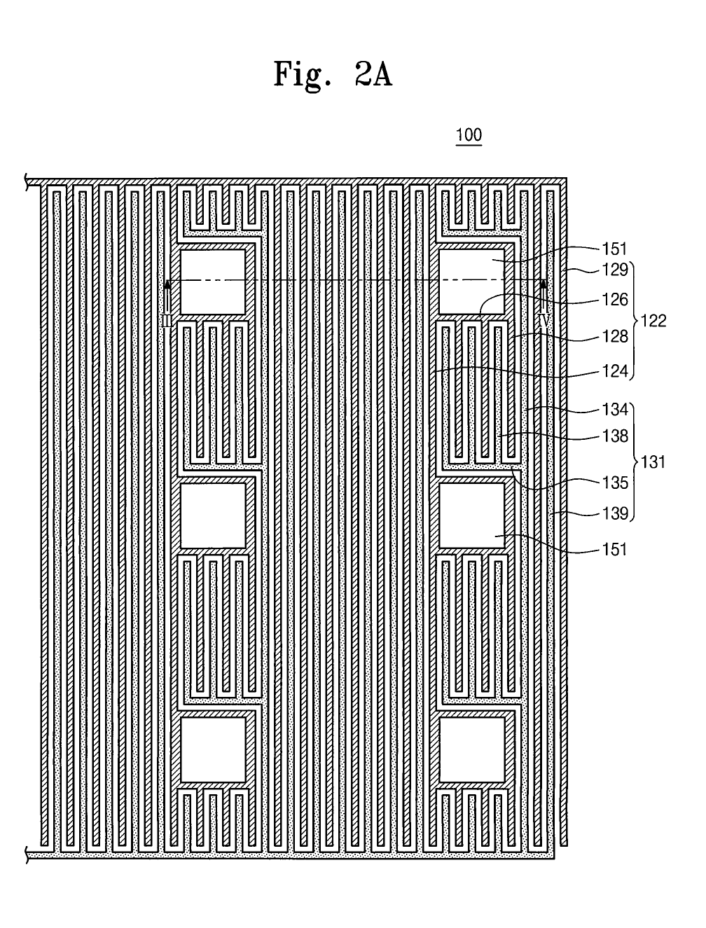

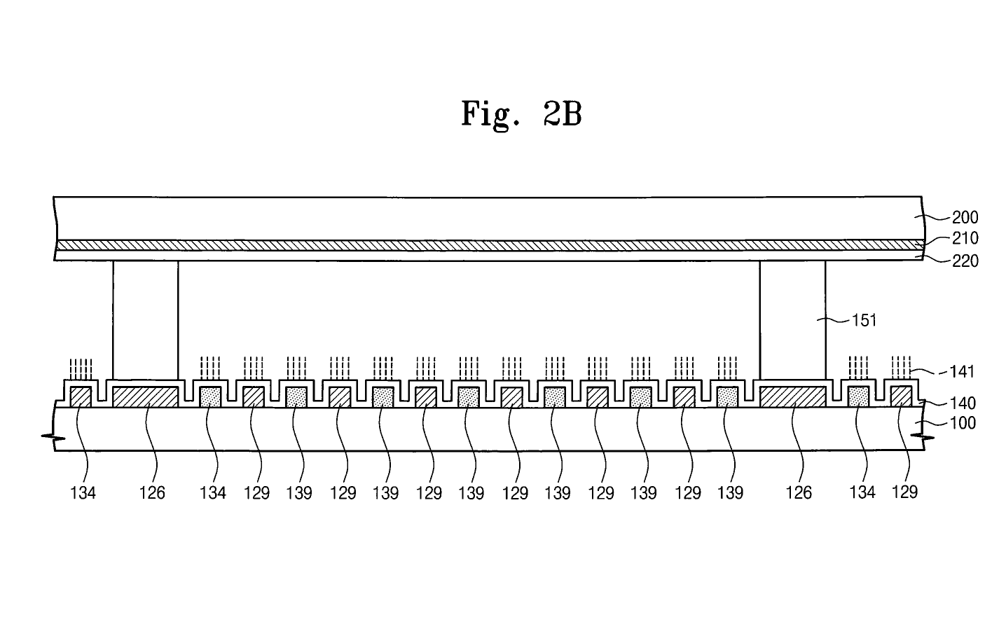

Referring to FIGS. 2A and 2B, a field emission device according to another embodiment of the inventive concept will now be described below in detail. FIG. 2B is a cross-sectional view taken along the line III-IV in FIG. 2A. The same numerals in FIGS. 2A and 2B as those in FIGS. 1A and 1B denote the same elements, and different elements in FIGS. 2A and 2B from those in FIGS. 1A and 1B will now be explained below.

Referring to FIG. 2, a cathode electrode 122 may include a first cathode line 124 extending in a first direction, second cathode lines branching from the first cathode line 124 and extending a second direction which is not in parallel with the first direction, and a third cathode line 128 branching from the second cathode lines 126 and extending in a third direction which is not in parallel with the second direction. Widths of the first cathode line 124 and the third cathode line 128 may be substantially equal to each other. Widths of the second cathode lines 126 may be greater than those of the first and third cathode lines 124 and 128. In this specification, widths of the lines are each defined as a width in a perpendicular direction to directions in which the lines extend. For example, the width of the second cathode line 126 indicates that of the second cathode line 126 in a perpendicular direction to the second direction.

A spacer 151 may be disposed on the insulating layer 140 on the second cathode lines 126. However, one spacer 151 may be disposed one second cathode line 126. A plurality of spacers 151 may be disposed on one second cathode line 126. Unlike illustrated, one spacer 151 may be disposed on the one second cathode line 126. The entire bottom surface of the spacer 151 may be disposed on the second cathode line 126. That is, the spacer 151 does not protrude in a horizontal direction of a substrate plane from a top surface of the second cathode line 126. Entire top and bottom surfaces of the spacer 151 overlap to be perpendicular to the second cathode line 126. For achieving this, the width of the spacer 151 may be substantially equal to that of the second cathode line 126 or may be substantially less than that of the second cathode line 126.

Since the spacer 151 is disposed on one second cathode line 126, it may prevent a phenomenon such as electrical conducting occurring by the spacer 151 between adjacent second cathode lines 126. In the case that one spacer is formed on a plurality of gate lines and/or a plurality of cathode lines, arching and/or abnormal emitting effect may occurs due to charging and discharging which are continuously conducted between a plurality of lines connected to the one spacer. However, according to embodiments of the inventive concept, because the spacer 151 is formed on one electrode line, electric conducting occurring by the spacer 151 between adjacent electrode lines may be suppressed. Thus, a field emission device with improved reliability may be provided.

Unlike illustrated, a shape of the cathode electrode 122 and a shape of the gate electrode 131 may be reversed. That is, the cathode electrode 122 may be formed to have a shape of the gate electrode 131 shown in FIG. 2A and the gate electrode 131 may be formed to have a shape of the cathode electrode 122 shown in FIG. 2A.

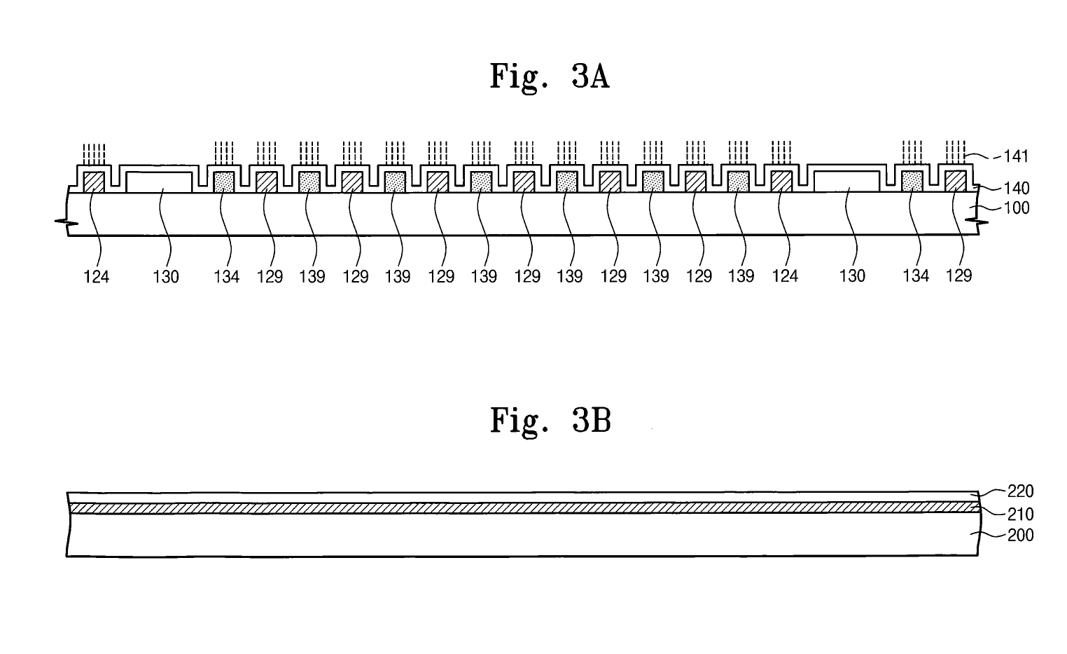

Referring to FIGS. 1A, 1B, 3A, and 3B, a method of forming a field emission device according to embodiments of the inventive concept will now be described below in detail. FIG. 3A is a cross-sectional view of a cathode substrate of a field emission device, which is taken along the line I-II in FIG. 1A. FIG. 3B is a cross-sectional view of an anode substrate opposite to the cathode substrate. Explanations of the above-described elements may be emitted.

Referring to FIGS. 1A and 3A, a cathode electrode 121 is formed on a cathode substrate 100. A conductive layer may be formed on the cathode substrate 100. The conductive layer may include at least one selected from the group consisting of metals containing silver (Ag), chrome (Cr), aluminum (Al), nickel (Ni), cobalt (Co), platinum (Pt), gold (Au), titanium (Ti), tungsten (W), and zinc (Zn). Alternatively, the conductive layer may include at least one of conductive metal compounds containing indium tin oxide (ITO). The conductive layer may be patterned to form a cathode electrode 121. The conductive layer may be patterned by means of a photolithography process. The patterned conductive layer may be sintered.

A gate electrode 131 is formed on the cathode substrate 100. The gate electrode 131 may be formed of a same method as the forming of the cathode electrode 121. Alternatively, the gate electrode 131 and the cathode electrode 121 may be simultaneously formed.

A pattern 130 may be formed on the cathode electrode 100. The pattern 130 may be a conductive pattern or an insulating pattern that is electrically insulated from the gate electrode 131 and the cathode electrode 121. Alternatively, the formation of the pattern 130 may be omitted. In this case, a cathode substrate having the shape shown in FIG. 1C may be formed.

The gate electrode 131 and the cathode electrode 121 may be formed to have different shapes. Referring to a cathode electrode portion shown in FIG. 2B, the cathode electrode 121 may be formed to include a second cathode line 126 having a relatively great width. Shapes of the electrodes 121 and 131 may be adjusted by a shape of a mask for use in a photolithography process during formation of the electrodes 121 and 131.

An insulating layer 140 is formed on the gate electrode 131 and the cathode electrode 121. The insulating layer 140 may conformally cover the gate electrode 131 and the cathode electrode 121. Alternatively, the insulating layer 140 may have a planarized top surface while filling a space between the gate electrode 131 and the cathode electrode 121. The insulating layer 140 may be formed by means of a printing process.

An emitter 141 may be formed on the insulating layer 140. The emitter 141 may be formed by means of a screen printing process. The emitter 141 may include a carbon nanotube. A carbon nanotube formed on the insulating layer 140 may be sintered.

Referring to FIG. 3B, an anode electrode 210 and a phosphor layer 220 may be sequentially formed on an anode substrate 200.

Returning to FIG. 1B, the anode substrate 200 and the cathode substrate 100 are adhered to each other. A spacer 151 may be interposed between the anode substrate 200 and the cathode substrate 100 to maintain a distance therebetween.

The spacer 151 may be formed on one surface of the cathode substrate 100 where the cathode electrode 131 and the gate electrode 121 are not disposed. The spacer 151 may be adhered between the anode substrate 200 and the cathode substrate 100 by various adhering means including an ultraviolet glue (UV glue). A state between the anode substrate 200 and the cathode substrate 100 is preferably a vacuum state. For achieving this, a vacuum packaging process may be performed.

In the case that one spacer is formed on a plurality of gate electrode lines and/or a plurality of cathode electrode lines, electrical characteristics between the gate electrode lines and/or the cathode electrode lines may be degraded during the vacuum packaging process. More specifically, the electrode lines are short-circuited by a section state of the spacer or pressure caused by a weight of the spacer, or adjacent electrode lines may be electrically conducted by glue for adhering the spacer. However, according to embodiments of the inventive concept, since the spacer 151 is not formed on a plurality of the electrode lines, degradation in electric characteristics of the electrode lines by a process of forming the spacer 151 may be prevented. Thus, process stability may be enhanced.

According to embodiments of the inventive concept, a gate electrode and a cathode electrode constituting one driving region can include a plurality of lines extending in a plurality of directions. Thus, a luminous effect of a field emission device including the gate electrode and the cathode electrode can be improved.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A field emission device comprising:
a gate electrode including a first gate line extending a first direction of a first substrate, a plurality of second gate lines branching from the first gate line and extending a second direction that is not in parallel with the first direction, and third gate lines branching from the second gate lines;
a cathode electrode including a first cathode line being in parallel with the first gate line on the first substrate, a plurality of second cathode lines branching from the first cathode line and being in parallel with the second gate lines, and third cathode lines branching from the second cathode lines and being interlocked with the third gate lines;
a second substrate disposed in parallel with the first substrate and spaced apart from the first substrate at a predetermined distance;
an anode electrode opposite to the gate electrode and the cathode electrode and a phosphor layer on the anode electrode, on the second substrate; and
a spacer making the first and second substrates spaced apart from each other,
wherein the gate electrode and the cathode electrode constitute a driving unit.

2. The field emission device of claim 1, wherein the spacer is disposed at a region on the first substrate where the gate electrode and the cathode electrode are not disposed.

3. The field emission device of claim 1, wherein the cathode electrode comprises second cathode lines having widths which are greater than those of the first and third cathode lines, and wherein widths of the first, second, and third cathode lines are defined as widths in perpendicular directions to directions of the first, second, and third direction, respectively.

4. The field emission device of claim 3, wherein the cathode electrode further comprises other second cathode lines having widths which are substantially equal to those of the first and third cathode lines.

5. The field emission device of claim 3, wherein an entire bottom surface of one spacer is disposed on one second cathode line.

6. The field emission device of claim 1, wherein the gate electrode comprises second gate lines having widths which are greater than those of the first and third gate lines, and
wherein widths of the first, second, and third gate lines are defined as widths in perpendicular directions to directions of the first, second, and third direction, respectively.

7. The field emission device of claim 6, wherein the gate electrode further comprises other second gate lines having widths which are substantially equal to those of the first and third gate lines.

8. The field emission device of claim 6, wherein an entire bottom surface of one spacer is disposed on one second gate line.

9. The field emission device of claim 1, further comprising:
a fourth cathode line disposed in parallel with the second cathode line and branching from the first cathode line; and
a fourth gate line disposed in parallel with the second gate line and branching from the first gate line,
wherein the fourth cathode line and the fourth gate line are alternately disposed.

10. The field emission device of claim 1, further comprising:
an insulating layer covering the gate electrode and the cathode electrode.

11. The field emission device of claim 10, wherein the insulating layer comprises a mixture of a low temperature glass fit and an inert inorganic particle.

12. The field emission device of claim 10, further comprising:
an emitter on the insulating layer, the emitter comprising a carbon nanotube.
